(19) United States
(12) Patent Application Publication
(10) Pub. No.: US 2007/0262365 A1
(43) Pub. Date: Nov. 15, 2007

(54) Solid-state imaging device and method of driving the same

(75) Inventors: Mariko Saito, Kurokawa-gun (JP); Katsumi Ikeda, Kurokawa-gun (JP)

Correspondence Address: BIRCH STEWART KOLASCH & BIRCH, PO BOX 747, FALLS CHURCH, VA, 22040-0747, US

(73) Assignee: FUJIFILM Corporation

(21) Appl. No.: 11/797,044

(22) Filed: Apr. 30, 2007

(30) Foreign Application Priority Data
May 15, 2006 (JP) P2006-135141

(51) Int. Cl. H01L 31/113; H01L 31/062

(52) U.S. Cl. 257/291

(57) ABSTRACT

A charge transfer section includes first transfer electrodes for effecting the reading and transfer of electric charges and the transfer of signal charges and second transfer electrodes each provided between adjacent ones of the first transfer electrodes to effect the transfer of the signal charges along the charge transfer section. A timing signal supplying section supplies a driving pulse signal to the first and second transfer electrodes when the signal charges are transferred along the charge transfer section, and supplies a pulse signal for constituting a barrier potential of a level at which the first transfer electrodes do not produce a dark current for photoelectric conversion elements when the transfer of the signal charges along the charge transfer section is stopped.

### BACKGROUND OF THE INVENTION

1. Field of the Invention

The present invention relates to a solid-state imaging device in which are formed charge transfer sections in which photoelectric conversion elements for generating electric charges by responding to light are arranged in a matrix form to transfer signal charges generated, as well as a method for driving the same.

2. Description of the Related Art

A solid-state imaging device 100 such as a CCD imaging device has pixel sections in which photoelectric conversion elements for generating electric charges by responding to light are arranged in a matrix form, as well as a plurality of charge transfer sections each provided adjacent to each column of the pixel sections in a strip form to transfer signal charges generated by the photoelectric conversion elements. In the charge transfer sections, electric charges are transferred by drive pulses which are supplied from a timing signal supplying section.

FIG. 12 is a diagram schematically illustrating the configuration of the related-art solid-state imaging device based on a four-phase drive.

Photoelectric conversion elements (photodiodes) PD1 to PD8 (only two columns of eight photodiodes are illustrated for the sake of simplicity in the illustrated example) which are arranged vertically are arrayed in a two-dimensional matrix form in a light receiving area of the solid-state imaging device. The photodiodes PD1 to PD8 will be individually or collectively referred to as the photodiodes PD. The photodiodes PD convert received light into signal charges and store them. A vertical charge transfer path 1 is provided in such a manner as to extend vertically alongside each column of photodiodes PD. A signal charge accumulated in each photodiode PD is read out to the vertical charge transfer path 1 on its side through a transfer gate 3.

Four-phase transfer electrodes V1 to V4 are repeatedly provided on each vertical charge transfer path 1, and two transfer electrodes are provided per photodiode PD.

A driver 5 supplies four-phase drive pulses φV1 to φV4 to the four-phase transfer electrodes V1 to V4, respectively, on each vertical charge transfer path 1. As a result, each vertical charge transfer path 1 transfers the signal charges upwardly (vertically) from below in the four-phase drive in response to the drive pulses φV1 to φV4.

In addition, the driver supplies two-phase drive pulses φH1 and φH2 to a horizontal charge transfer path 7. The horizontal charge transfer path 37 receives the charges from the vertical charge transfer paths 51 and transfers the charges from right to left (horizontally) in a two-phase drive in response to the drive pulses φH1 and φH2.

An output amplifier 9 receives the signal charges from the horizontal charge transfer path 7, amplifies the voltage corresponding to the amount of charge and outputs it. Thus, as the photodiodes are arranged in a two-dimensional matrix form, it is possible to obtain a two-dimensional image.

Next, a description will be given of a controlling method in an interlace mode. In the interlace mode, a set of image data in a first field and a second field constitute image data of one frame. First, to read out the image data of the first field, charges in the photodiodes PD1, PD3, PD5, and PD7 in odd-numbered rows are read out to positions corresponding to the electrodes V1 on each vertical charge transfer path 1. The charges on the vertical charge transfer paths 1 are transferred to the horizontal charge transfer path 7. Image data of the first field are outputted from the output amplifier 9.

Next, to read out the image data of the second field, charges in the photodiodes PD2, PD4, PD6, and PD8 in even-numbered rows are read out to positions corresponding to the electrodes V3 on each vertical charge transfer path 1. The charges on the vertical charge transfer paths 1 are transferred to the horizontal charge transfer path 7. Image data of the second field are outputted from the output amplifier 9.

FIG. 13 is a timing chart of four-phase drive pulses which are supplied to the vertical charge transfer paths in the related-art solid-state imaging device. FIG. 14 is a time chart illustrating a method of controlling the four-phase drive vertical charge transfer paths in the related-art solid-state imaging device.

The abscissa in FIGS. 13 and 14 shows the time. In the electrodes V1 to V4, a low-level voltage is applied to the electrodes shown hatched, as shown in FIG. 14, and the potential on the vertical charge transfer path corresponding to those electrodes is shallow. Meanwhile, a high-level voltage is applied to the electrodes shown unhatched, and the potential on the vertical charge transfer path corresponding to those electrodes is deep. Namely, packets are formed on the vertical charge transfer path of the unhatched electrodes, and charges are accumulated therein and transferred.

First, a description will be given of the case where the image data of the first field is read out. During a vertical transfer wait period S1, which is a horizontal transfer period, charges are read out from the photodiodes PD1 and PD3 in the odd-numbered rows to positions corresponding to the electrodes V1 on each vertical charge transfer path. At this time, in each vertical charge transfer path, the electrodes V3 and V4 are set to a high level to form a packet, whereas the electrodes V1 and V2 are set to a low level to form potential barriers.

At a time t1, the electrodes V3 and V4 are set to the high level to form a packet, whereas the electrodes V1 and V2 are set to the low level to form potential barriers.

At a time t2, the electrodes V1, V3, and V4 are set to the high level to form a packet, whereas the electrodes V2 are set to the low level to form potential barriers.

It is possible to understand the manner in which, with the lapse of time, the charge in the packet moves in the downward direction from above in the drawing. The times t1 to t8 constitute one cycle of the charge transfer, and of the four-phase electrodes V1 to V4, two electrodes V2 and V4 are set to the low level at the time t1, and one electrode is set to the low level at the time t2.

The controlling method in the four-phase drive is as described above.

Next, a description will be given of the vertical charge transfer paths in the case where the above-described four-phase drive is changed to an eight-phase drive. FIG. 15 is a diagram schematically illustrating the configuration of the related-art solid-state imaging device. FIG. 16 is a timing chart of eight-phase drive pulses which are supplied to the vertical charge transfer paths in the related-art solid-state imaging device. FIG. 17 is a time chart illustrating a method of controlling the eight-phase drive vertical charge transfer paths in the related-art solid-state imaging device.

A vertical charge transfer path 1 is provided alongside each column of photodiodes PD, and eight-phase electrodes V1 to V8 are provided thereon. The other arrangements are similar to those of the four-phase drive solid-state imaging device shown in FIG. 12. In FIGS. 16 and 17, the abscissa shows the time. As for the electrodes V1 to V8, the meanings of the electrodes shown hatched and the electrodes shown unhatched are similar to those described above. Eight-phase drive pulses are supplied to the electrodes V1 to V8 on the vertical charge transfer paths, and the vertical charge transfer paths transfer signal charges in the eight-phase drive.

During the vertical transfer wait period S1, charges are read out from the photodiodes PD1 and PD5 to positions corresponding to the electrodes V1 on each vertical charge transfer path. At this time, in the vertical charge transfer paths, two electrodes V5 and V6 are set to the high level to form a packet, whereas six electrodes V1, V2, V3, V4, V7, and V8 are set to the low level to form potential barriers. The same holds true of the time t1. The time t1 may be omitted.

At the time t2, three electrodes V5, V6, and V7 are set to the high level to form a packet, whereas five electrodes V1, V2, V3, V4, and V8 are set to the low level to form potential barriers.

At a time t3, two electrodes V6 and V7 are set to the high level to form a packet, whereas six electrodes V1, V2, V3, V4, V5 and V8 are set to the low level to form potential barriers.

With the lapse of time, the charge in the packet moves in the downward direction from above. The times t1 to t17 constitute one cycle. In the eight-phase drive, alternately numbered photodiodes PD are adapted to read out the charges in comparison with the above-described four-phase drive, so that this arrangement is suitable for an interlaced drive (See JP-A-2000-196066).

However, with the above-described related-art driving method of the solid-state imaging device, in the vertical transfer electrodes, continuous n electrodes (n=2 or more) are used as storage electrodes, and the remaining electrodes are used as barrier electrodes. For this reason, there has been a problem in that white defects increase if readout electrodes are included when the continuous n electrodes (n=2 or more) are used as storage electrodes.

FIG. 18A is a cross-sectional view taken along line I-I of FIG. 12, and FIG. 18B is a schematic diagram illustrating a potential distribution of FIG. 18A.

In the solid-state imaging device, as shown in FIG. 18A, a p-type impurity well layer 11 is formed on the surface of an n-type silicon substrate, and an insulating layer (not shown) formed of a SiN/SiO₂;SiN film (ONO film) is further formed thereon. In addition, a high-concentration p-type impurity layer 13 is formed at the surface of the impurity layer 11, and an n-type impurity layer 15 is further formed therebelow, thereby forming a photoelectric conversion element (photodiode) 17 which generates charge by responding to the light.

In addition, an n-type impurity layer 23 is formed in such a manner as to be located laterally of a readout gate 21 of the photodiode 17 away from the side where the p-type impurity layer 13 and the n-type impurity layer 15 are formed. An electrode 25 is formed on the surface of the insulating layer (not shown) above the n-type impurity layer 23, and this electrode is covered with an insulating layer (not shown). Further, in the solid-state imaging device, an element isolation zone (not shown) constituted by a high-concentration p-type impurity layer is formed in such a manner as to surround a region including the photodiode 17 and the n-type impurity layer 23 serving as the vertical charge transfer path.

In the solid-state imaging device having the above-described configuration, as a sufficiently high voltage is applied to the electrode 25, a barrier (P-well region) 27 toward the vertical charge transfer path 1 with respect to the potential of the photodiode 17 ceases to exist, as shown in FIG. 18B, so that the accumulated signal charge D moves to the vertical charge transfer path 1. The amount of charge of the signal charge D accumulated in the photodiode 17 is determined by the potential barrier of the overflow barrier constituted by the P-type well region 27, as shown in the potential distribution diagram in FIG. 18B. Namely, this overflow barrier determines the amount of saturated signal charge accumulated in the photodiode 17.

In the related-art art, in the period S1, two or more continuous electrodes 25 are used as storage electrodes, and readout electrodes and electrodes which are not readout electrodes are arranged alternately. For this reason, as shown in FIGS. 14 and 17, the readout electrodes V4 and V6 are included as the storage electrodes among the electrodes 25, so that a depleted region 29 is formed on the surface layer of the readout gate 21 of the photodiode 17 as in Evx=Mid (a voltage value corresponding to a low voltage during the vertical charge transfer in the storage electrode) in the potential diagram shown in FIG. 18B. Namely, as a mid-level voltage having a higher voltage value than the low level is applied to the readout electrodes V4 and V6, the depleted region 29 is formed. If the depleted region 29 occurs, free electrons which are present in the vicinity of the interface flow into the photodiode 17 as a charge e, and is added to the normally accumulated signal charge D (D+e) and is accumulated as a dark current, thereby resulting in the occurrence of a white defect due to that dark current component.

### SUMMARY OF THE INVENTION

The invention has been devised in view of the above-described circumstances, and its object is to provide a solid-state imaging device in which a depleted region does not occur in the readout gate of the photodiode, and a dark current is not accumulated in the photodiode, as well as a method of driving the same, thereby reducing white deflects contained in the image data.

The above object in accordance with the invention is attained by the following configurations:

(1) A solid-state imaging device comprising:

pixel sections which are formed on a surface layer of a semiconductor substrate and in which photoelectric conversion elements for generating electric charges by responding to light are arranged in a matrix form in a plurality of rows and columns;

a plurality of charge transfer sections which are formed on the surface layer of the semiconductor substrate and which are each provided adjacent to each column of the pixel sections in a strip form to transfer signal charges generated by the photoelectric conversion elements; and

a timing signal supplying section for supplying a drive pulse for effecting the transfer of the electric charges by the charge transfer sections,

wherein each of the charge transfer sections has first transfer electrodes for effecting the reading and transfer of the electric charges from the photoelectric conversion elements and for effecting the transfer of the signal charges along the charge transfer sections, and second transfer electrodes each provided between adjacent ones of the first transfer electrodes to effect the transfer of the signal charges along the charge transfer sections, and

wherein the timing signal supplying section supplies a driving pulse signal to the first and second transfer electrodes when the signal charges are transferred along the charge transfer sections, and supplies a pulse signal for constituting a barrier potential of a level at which the first transfer electrodes do not produce a dark current for the photoelectric conversion elements when the transfer of the signal charges along the charge transfer sections is stopped.

According to this solid-state imaging device, except during the transfer, a barrier potential of a level for constituting storage electrodes is not applied to readout electrodes. Namely, except during the transfer, the electrodes are set as storage electrodes by shunting the readout electrodes. Consequently, even in a case where the readout electrodes and two or more continuous electrodes which are not readout electrodes are alternately arranged as storage electrodes, a voltage at the level of a storage electrode ceases to be applied to the readout electrodes.

Therefore, a depleted region is not produced at the readout gate of the photodiode, and electrons which are present in the vicinity of the interface cease to flow into the photodiode as a charge. As a result, electrons are not accumulated in the photodiode as the charge.

(2) The solid-state imaging device according to item (1), wherein the signal charges which are transferred are electrons, and the pulse signal for constituting the barrier potential is a low-level signal.

According to this solid-state imaging device, when the transfer is stopped, a low-level voltage is applied from the timing signal supplying section to the first transfer electrodes, and the potential on the vertical charge transfer paths corresponding to those electrodes becomes shallow. At this time, the barrier does not undergo thinning which occurs on application of a mid- or high-level voltage during the vertical charge transfer, so that a depleted region which causes electrons to be generated is not formed.

(3) A method of driving a solid-state imaging device including pixel sections which are formed on a surface layer of a semiconductor substrate and in which photoelectric conversion elements for generating electric charges by responding to light are arranged in a matrix form in a plurality of rows and columns, a plurality of charge transfer sections which are formed on the surface layer of the semiconductor substrate and which are each provided adjacent to each column of the pixel sections in a strip form to transfer signal charges generated by the photoelectric conversion elements, and a timing signal supplying section for supplying a drive pulse for effecting the transfer of the electric charges by the charge transfer sections, comprising the steps of:

when the signal charges are transferred along the charge transfer sections, supplying a driving pulse signal to first transfer electrodes for effecting the reading and transfer of the electric charges from the photoelectric conversion elements and for effecting the transfer of the signal charges along the charge transfer sections and to second transfer electrodes each provided between adjacent ones of the first transfer electrodes to effect the transfer of the signal charges along the charge transfer sections, and

when the transfer of the signal charges along the charge transfer sections is stopped, supplying a pulse signal for constituting a barrier potential of a level at which the first transfer electrodes do not produce a dark current for the photoelectric conversion elements.

According to the method of driving a solid-state imaging device, the timing signal supplying section does not apply a barrier potential of such a level as to constitute a storage electrode to the readout electrode except during the transfer. Namely, except during the transfer, the electrodes are set as storage electrodes by shunting the readout electrodes. Consequently, even in a case where readout electrodes and two or more continuous electrodes which are not readout electrodes are alternately driven as storage electrodes, a voltage at the level of a storage electrode is not applied to the readout electrode, so that a depleted region is not produced at a readout gate of the photodiode. Therefore, electrons which are present in the vicinity of the interface cease to flow into the photodiode as a charge.

(4) The method of driving a solid-state imaging device according to item (3), wherein the driving pulse signal is a pulse signal for a four-phase drive.

According to the method of driving a solid-state imaging device, of the four-phase electrodes, at different times two electrodes are set to the low level, while one electrode is set to the low level, which arrangement is alternately repeated. Consequently, the signal charge from all the photoelectric conversion elements can be fetched in a single operation.

(5) The method of driving a solid-state imaging device according to item (3), wherein the driving pulse signal is a pulse signal for an eight-phase drive.

According to the method of driving a solid-state imaging device, since the charge in every other photoelectric conversion element is readout, the driving method is suitable for an interlaced drive.

### BRIEF DESCRIPTION OF THE DRAWINGS

FIG. 1 is a diagram schematically illustrating the configuration of the solid-state imaging device in accordance with the invention;

FIG. 2 is a plan view illustrating the layout of vertical transfer paths in a four-phase drive;

FIG. 3 is a schematic diagram illustrating the layout of electrodes in the four-phase drive;

FIG. 4 is a timing chart of four-phase drive pulses which are supplied to the vertical charge transfer paths shown in FIG. 2;

FIG. 5 is a time chart illustrating a method of controlling the four-phase drive vertical charge transfer paths in the solid-state imaging device in accordance with the invention;

FIG. 6 is a plan view illustrating the layout of the vertical transfer paths in an eight-phase drive;

FIG. 7 is a schematic diagram illustrating the layout of electrodes in the eight-phase drive;

FIG. 8 is a timing chart of eight-phase drive pulses which are supplied to the vertical charge transfer paths shown in FIG. 6;

FIG. 9 is a time chart illustrating a method of controlling the eight-phase drive vertical charge transfer paths in the solid-state imaging device in accordance with the invention;

FIG. 10 is a plan view illustrating the layout of vertical transfer paths in the four-phase drive in a square lattice structure;

FIG. 11 is a schematic diagram illustrating the layout of electrodes in the four-phase drive in the square lattice structure;

FIG. 12 is a diagram schematically illustrating the configuration of the related-art solid-state imaging device;

FIG. 13 is a timing chart of four-phase drive pulses which are supplied to the vertical charge transfer paths in the related-art solid-state imaging device;

FIG. 14 is a time chart illustrating a method of controlling the four-phase drive vertical charge transfer paths in the related-art solid-state imaging device;

FIG. 15 is a diagram schematically illustrating the configuration of the related-art solid-state imaging device;

FIG. 16 is a timing chart of eight-phase drive pulses which are supplied to the vertical charge transfer paths in the related-art solid-state imaging device;

FIG. 17 is a time chart illustrating a method of controlling the eight-phase drive vertical charge transfer paths in the related-art solid-state imaging device;

FIG. 18A is a cross-sectional view taken along line I-I of FIG. 12; and

FIG. 18B is a schematic diagram illustrating a potential distribution of FIG. 18A.

### DETAILED DESCRIPTION OF THE INVENTION

Referring now to the accompanying drawings, a detailed description will be given of the preferred embodiments of a solid-state imaging device and a method of driving the same in accordance with the invention.

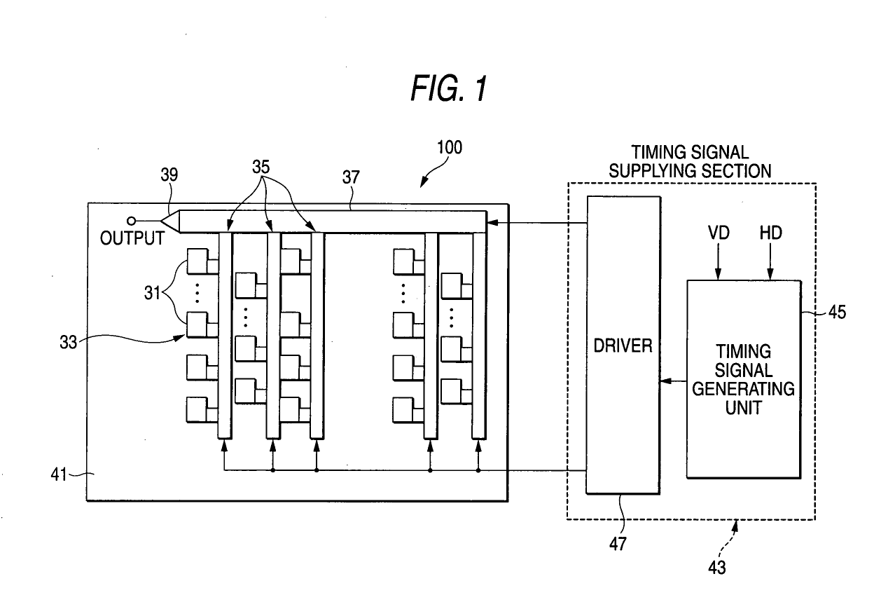

FIG. 1 is a diagram schematically illustrating the configuration of the solid-state imaging device in accordance with the invention.

A solid-state imaging device 100 such as a CCD in accordance with this embodiment has formed on a surface layer of a substrate 41 pixel sections 33 in which photoelectric conversion elements (photodiodes) 31 for generating electric charges by responding to light are arranged in a matrix form in a plurality of rows and columns; a plurality of vertical shift registers 35 each provided adjacent to each column of the pixel sections 33 to transfer in the column direction signal charges generated by the photoelectric conversion elements 31; a horizontal transfer section (horizontal shift register) 37 disposed at one end side in the column direction of each vertical shift register 35 to transfer in the row direction the signal charges transferred from the vertical shift registers 35; an output amplifier 39 connected to a downstream side in the charge transfer direction of this horizontal shift register 37 to convert the signal transferred thereto into a voltage value and to output it; overflow drains adjacent to the respective photodiodes 31. It should be noted that the substrate 41 constitutes the overflow drains.

The solid-state imaging device 100 is further provided with a timing signal supplying section 43 for inputting a drive signal. The timing signal supplying section 43 is configured by including a timing signal generating unit 45 for generating various pulse signals for driving the solid-state imaging device 100 on the basis of a horizontal synchronization signal HD and a vertical synchronization signal VD; a driver 47 for converting the various pulses supplied thereto from the timing signal generating unit 45 into drive pulses (a vertical transfer pulse and a horizontal transfer pulse) of predetermined levels; and an unillustrated substrate voltage generating unit for applying a drain voltage V_{DD} to the solid-state imaging device 100 on the basis of a timing signal from the timing signal generating unit 45. The drive of the solid-state imaging device 100 is controlled in accordance with an output signal from the timing signal supplying section 43.

In this solid-state imaging device 100, as the timing signal is sent from the timing signal generating unit 45 of the timing signal supplying section 43 to the substrate voltage generating unit, the drain voltage V_{DD} for sweeping the charges of the photodiodes 31 to the substrate 41 side is applied to the overflow drain (substrate 41) during the period from the time the signal charges are read out from the photodiodes 31 to the vertical shift register 35 until all the signal charges read out are transferred to the output amplifier 39.

Here, this drain voltage V_{DD} is such a voltage that the potential barrier (P-well region) formed in the overflow drain region allows the charges accumulated in the photodiodes 31 to be swept to the substrate 41 side. As a result, the potential barrier becomes low such as to allow the charges accumulated in the photodiodes 31 to be swept to the substrate 41 side, so that the charges accumulated in the photodiodes 31 can be drained to the substrate 41 side by crossing over the P-well region.

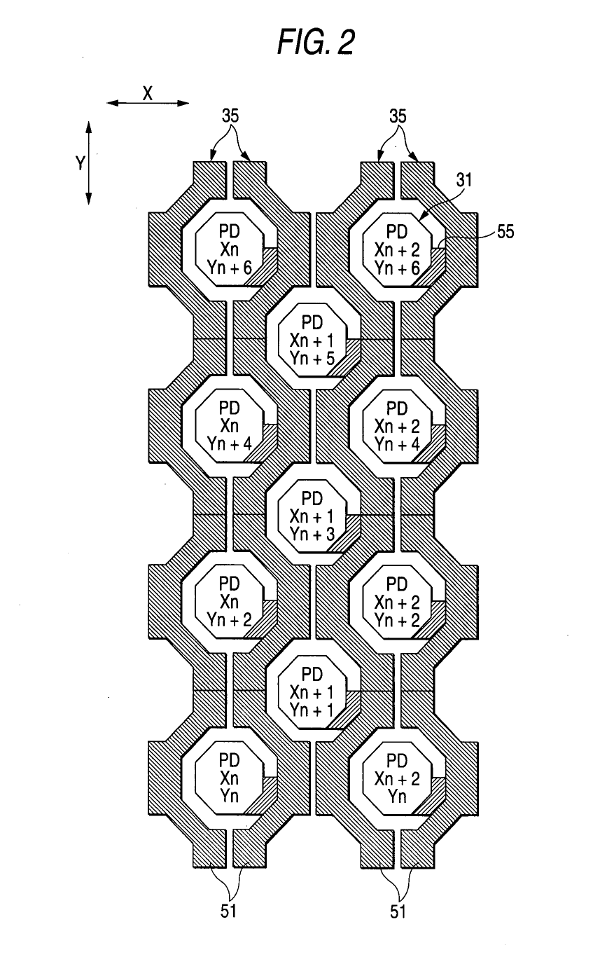

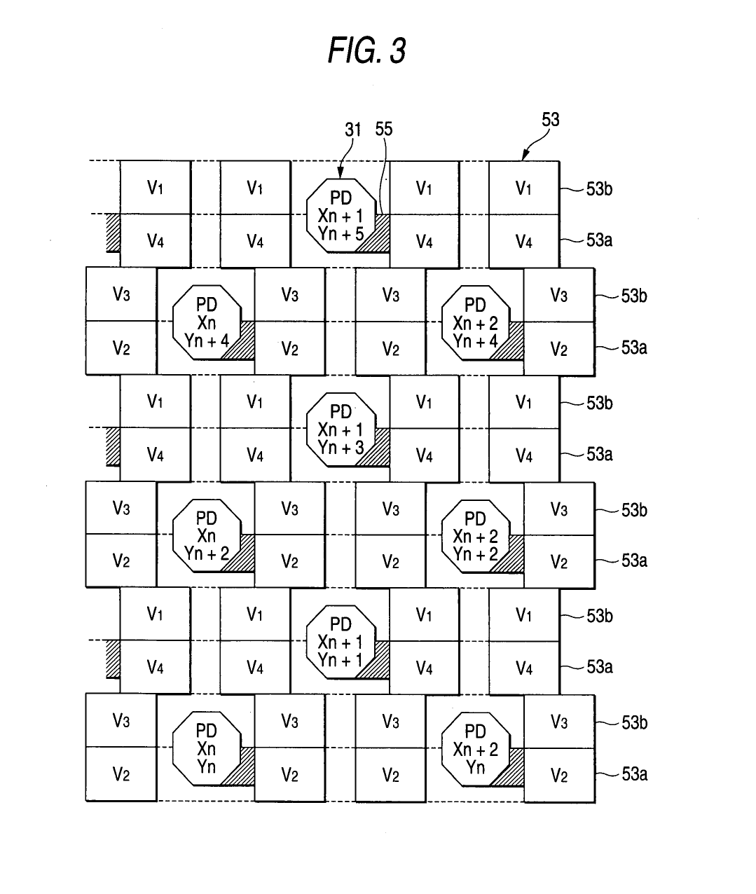

FIG. 2 is a plan view illustrating the layout of vertical transfer paths in a four-phase drive, and FIG. 3 is a schematic diagram illustrating the layout of electrodes in the four-phase drive.

As shown in FIG. 2, in the solid-state imaging device 100, the photodiodes 31 (PD Xn+1) of odd-numbered columns (or even-numbered columns) are formed with a positional offset of a half pitch, i.e., a phase difference, with respect to the photodiodes 31 (PD Xn) arranged in even-numbered columns in the vertical direction Y.

In the solid-state imaging device 100 having the so-called honeycomb structure in which the plurality of photodiodes 31 are thus disposed by being offset by a half pitch in the column direction, vertical charge transfer paths 51 constituted by the vertical shift registers 35 are formed in the substrate 41 along the photodiodes 31 in such a manner as to meander in a wavelike pattern. As shown in FIG. 3, transfer electrodes 53 shown in FIG. 3 and extending in a perpendicular direction to the vertical charge transfer paths 51 of this wavelike pattern are formed on the substrate 41. The transfer electrodes 53 are formed as four-phase transfer electrodes V1 to V4 are repeatedly. In this embodiment, of these transfer electrodes V1 to V4, those connected to the photodiodes 31 through transfer gates 55 are referred to as first transfer electrodes (V2, V4) 53a, whereas those not connected to the photodiodes 31 are referred to as second transfer electrodes (V1, V3) 53b.

The first transfer electrode 53a effects the reading and transfer of charge from the photodiode 31 and the transfer of signal charge along the charge transfer section (vertical charge transfer path 51). The second transfer electrode 53b is provided between the first transfer electrodes 53a and effects the transfer of signal charge along the charge transfer section (vertical charge transfer path 51). When signal charges are transferred along the vertical charge transfer paths 51, the timing signal supplying section 43 supplies a driving pulse signal to the first and second transfer electrodes 53a and 53b. Meanwhile, when the transfer of signal charges along the vertical charge transfer paths 51 is stopped, the timing signal supplying section 43 supplies a pulse signal for constituting a barrier potential of a level at which the first transfer electrodes 53a do not to produce a dark current for the photodiodes 31.

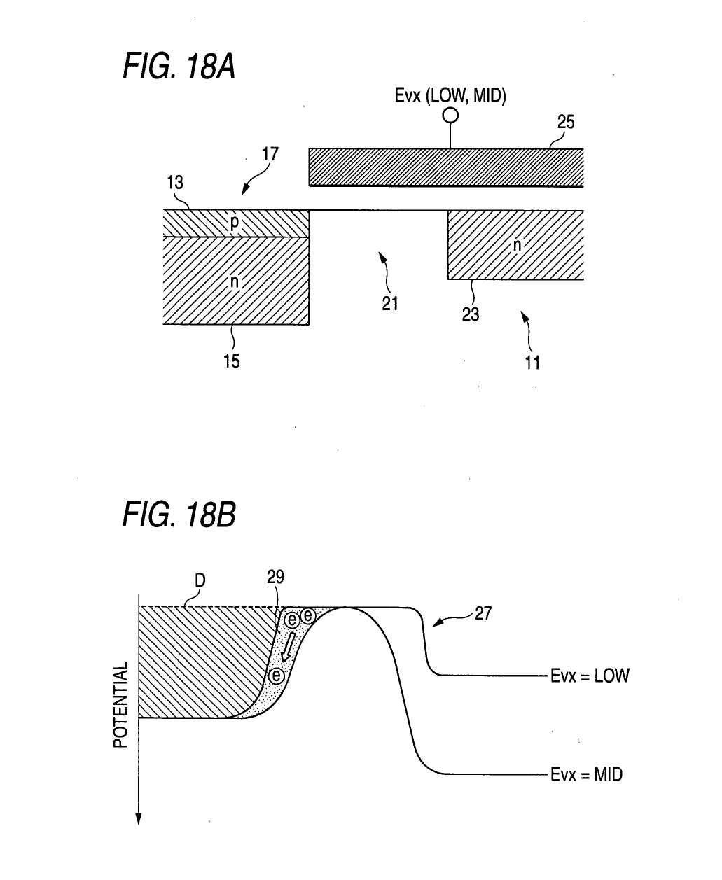

More specifically, the signal charges which are transferred by the vertical charge transfer paths 51 are electrons, and the pulse signal which provides the barrier potential is an OFF signal of a low level (e.g., 0 V). When the transfer is stopped, the low-level voltage is applied from the timing signal supplying section 43 to the first transfer electrodes 53a, and the potential on the vertical charge transfer paths 51 corresponding to those electrodes (V2, V4) becomes high. The arrangement provided is such that, at this time, the barrier does not undergo thinning which occurs on application of a mid-level voltage during the vertical charge transfer, so as to prevent a depleted region 29 (see FIG. 18) which causes electrons to be generated from being formed at a readout gate of the photodiode 31.

In other words, except during the transfer of the signal charge, a barrier potential of such a level as to constitute a storage electrode is not applied to the first transfer electrode 53a serving as a readout electrode. Namely, except during the transfer, the electrodes are set as storage electrodes by shunting the readout electrodes. Consequently, even in a case where readout electrodes and two or more continuous electrodes which are not readout electrodes (the first transfer electrodes 53a and the second transfer electrodes 53b) are alternately arranged as storage electrodes, a voltage at the level of a storage electrode ceases to be applied to the first transfer electrode 53a which is a readout electrode. Therefore, a depleted region is not produced at a readout gate 21 of the photodiode 31, and electrons which are present in the vicinity of the interface cease to flow into the photodiode 31 as a charge, so that electrons cease to be accumulated in the photodiode 31 as the charge.

Next, a description will be given of a method of driving the above-described solid-state imaging device.

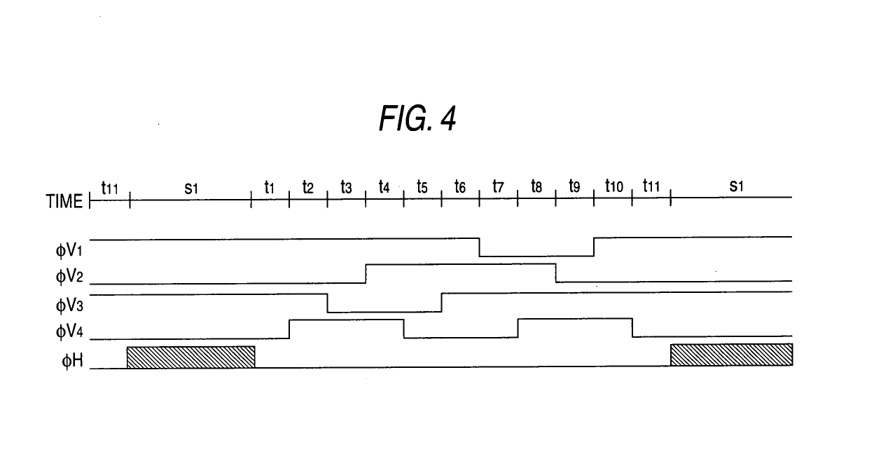

FIG. 4 is a timing chart of four-phase drive pulses which are supplied to the vertical charge transfer paths shown in FIG. 2.

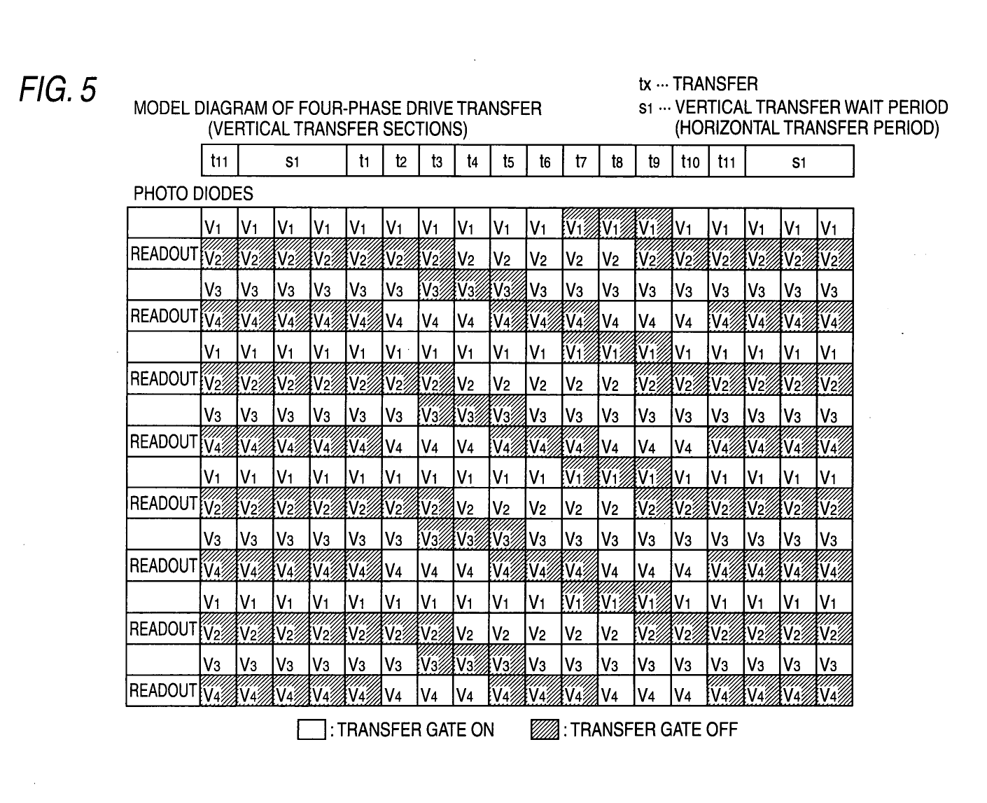

FIG. 5 is a time chart illustrating a method of controlling the four-phase drive vertical charge transfer paths in the solid-state imaging device in accordance with the invention.

In the method of driving the solid-state imaging device in accordance with this embodiment, since the driving pulse signal is the pulse signal for the four-phase drive, of the four-phase electrodes, at different times two electrodes are set to the low level, while one electrode is set to the low level, which arrangement is alternately repeated. Consequently, the charge in a packet is moved.

Times t1 to t11 constitute one cycle of the vertical charge transfer, and of the four-phase electrodes V1 to V4, two electrodes V2 and V4 are set to the low level at the time t1.

The driver 47 supplies four-phase drive pulses φV1 to φV4 to each vertical charge transfer path 51. Specifically, the drive pulse φV2 is supplied to the electrodes V1; the drive pulse φV2 is supplied to the electrodes V2; the drive pulse φV3 is supplied to the electrodes V3; and the drive pulse φV4 is supplied to the electrodes V1. Each vertical charge transfer path 51 transfers the charges upwardly (vertically) from below in the four-phase drive in response to the drive pulses φV1 to φV4. The driver 47 supplies two-phase drive pulses φH1 and φH2 to the horizontal charge transfer path 37. The horizontal charge transfer path 37 receives charges from the vertical charge transfer paths 51 and transfers the charges from right to left (horizontally) in response to the drive pulses φH1 and φH2.

In the electrodes V1 to V4 on each vertical charge transfer path 51, a low-level voltage is applied to the electrodes shown hatched in FIG. 5, and the potential on the vertical charge transfer path 51 corresponding to those electrodes is shallow. Meanwhile, a high-level voltage is applied to the electrodes shown unhatched, and the potential on the vertical charge transfer path 51 corresponding to those electrodes is deep. Namely, packets are formed on the vertical charge transfer path of the unhatched electrodes, and charges are accumulated therein and transferred.

During the vertical transfer wait period S1, which is a horizontal transfer period, charges are read out from the photodiodes 31 to each vertical charge transfer path 51. At this time, in the vertical charge transfer paths 51, the electrodes V1 and V3 are set to a high level to form a packet, whereas the electrodes V2 and V4 are set to a low level to form potential barriers.

Namely, when signal charges are transferred along the vertical charge transfer paths 51, a driving pulse signal is supplied to the first transfer electrodes 53a for effecting the reading and transfer of charges from the photodiodes 31 and for effecting the transfer of signal charges along the vertical charge transfer path 51 and to the second transfer electrodes 53b for effecting the transfer of signal charges along the vertical charge transfer path 51. Meanwhile, when the transfer of signal charges along the vertical charge transfer paths 51 is stopped, a pulse signal is supplied for constituting a barrier potential of a level at which the first transfer electrodes 53a do not to produce a dark current for the photodiodes 31.

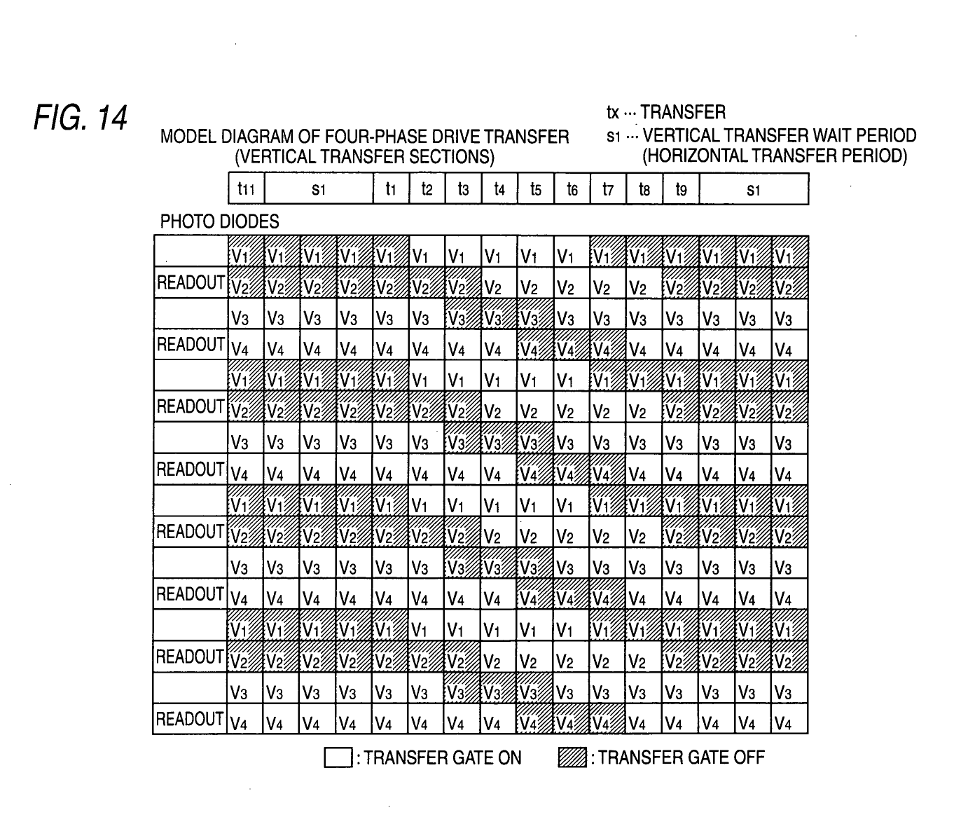

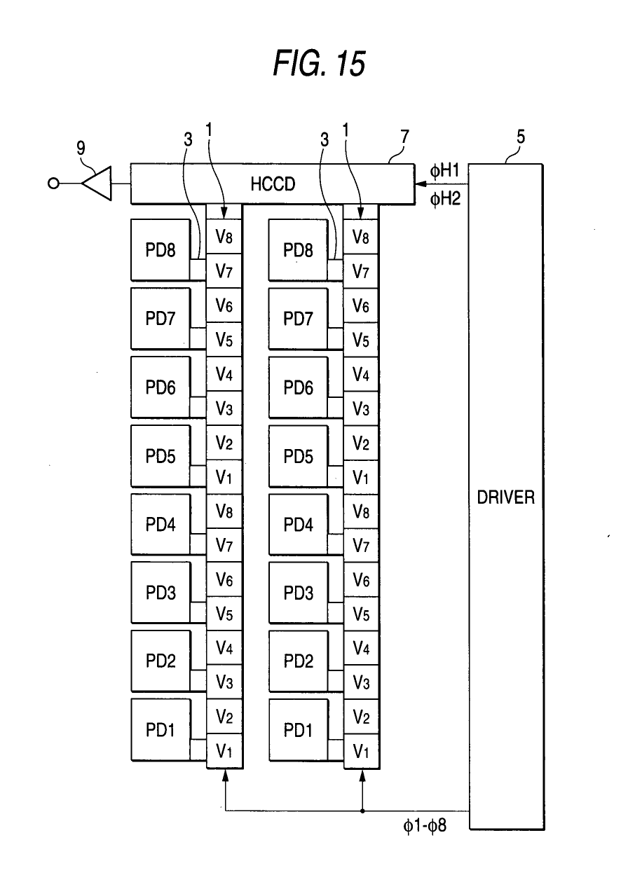

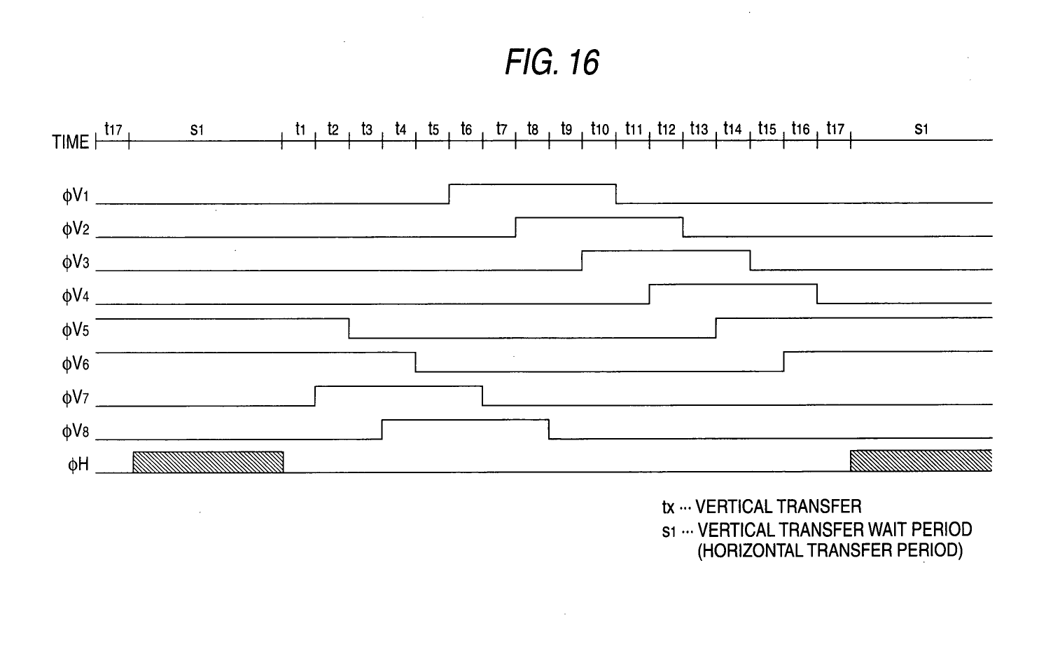

Thus, although the readout electrodes (electrodes V2 and V4 connected to the photodiodes 31 through transfer gates 55) are in the related art set to the mid level higher than the low level during the vertical transfer wait period S1, as shown in FIG. 14, the readout electrodes in this embodiment (electrodes V2 and V4 connected to the photodiodes 31 through transfer gates 55) are set to the low level with a voltage value lower than the mid level during the vertical transfer wait period S1, and the transfer gates are set in the off state, as shown in FIG. 5.

Therefore, according to the solid-state imaging device 100 in accordance with this embodiment, the timing signal supplying section 43 supplies a driving pulse signal to the first and second transfer electrodes 53a and 53b when signal charges are transferred along the charge transfer paths (vertical charge transfer paths 51), and supplies a pulse signal for constituting a barrier potential of a level at which the first transfer electrodes 53a do not to produce a dark current for the photodiodes 31 when the transfer of signal charges along the charge transfer sections is stopped. Hence, except during the transfer, a barrier potential of a level for constituting storage electrodes ceases to be applied to the readout electrodes V2 and V4. Namely, except during the transfer, the electrodes are set as storage electrodes by shunting the readout electrodes V2 and V4. Consequently, even in a case where the readout electrodes V2 and V4 and two or more continuous electrodes which are not readout electrodes are alternately arranged as storage electrodes, a voltage at the level of a storage electrode ceases to be applied to the readout electrodes V2 and V4. Therefore, a depleted region, such as Evx=Low shown in the potential diagram in FIG. 18, is not produced, and electrons which are present in the vicinity of the interface cease to flow into the photodiode 31 as a charge. As a result, a dark current ceases to be accumulated in the photodiode 31 as the charge, thereby making it possible to reduce white defects contained in the image data.

Next, a description will be given of another embodiment of the solid-state imaging device and the method of driving the same in accordance with the invention.

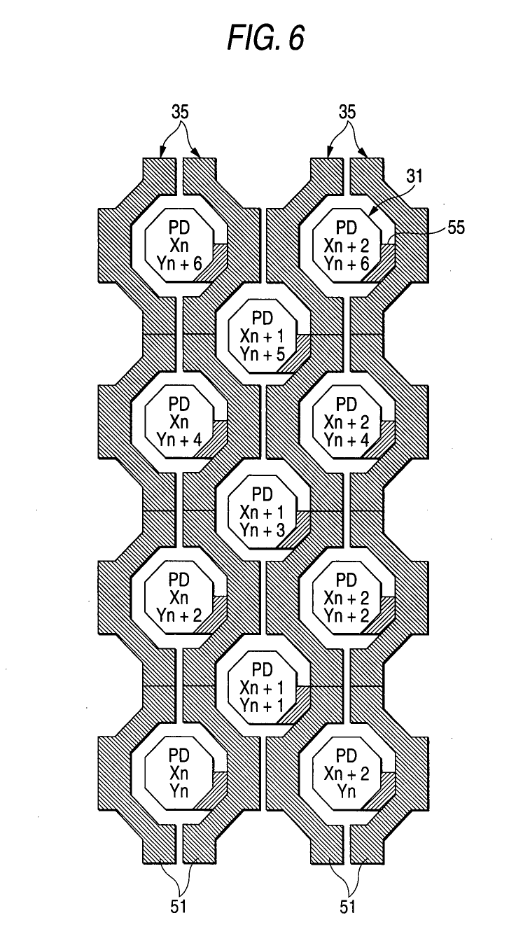

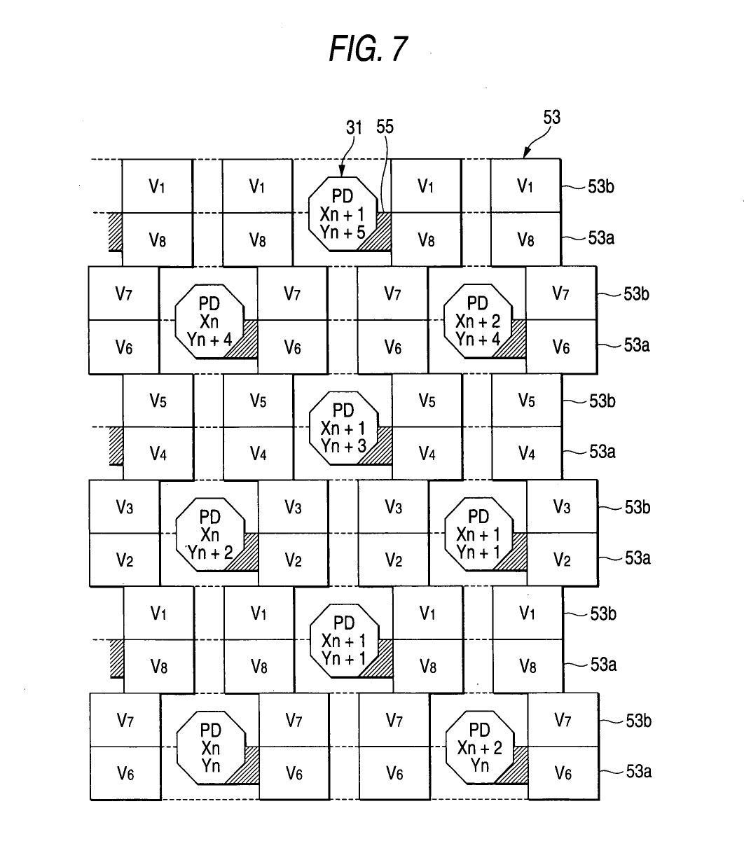

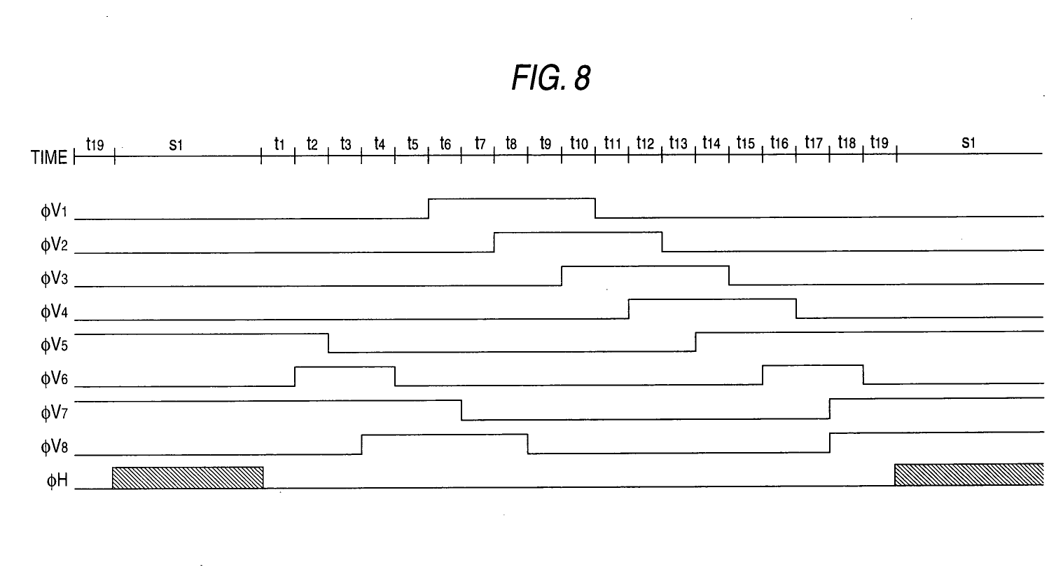

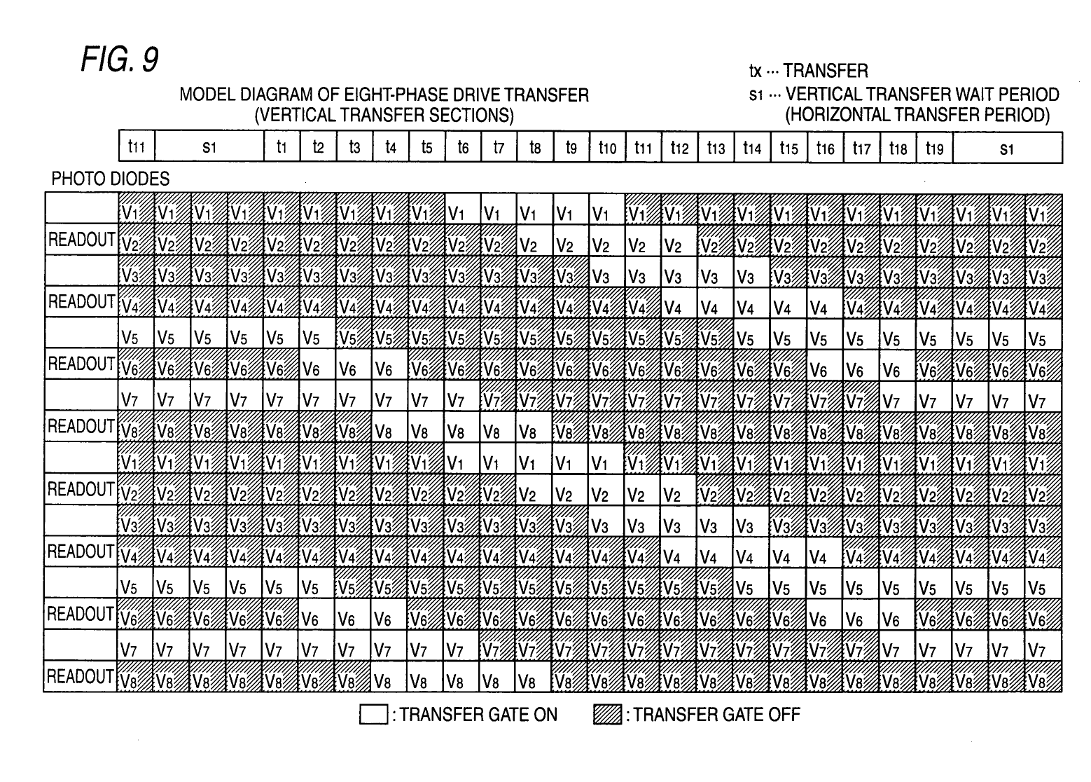

FIG. 6 is a plan view illustrating the layout of the vertical transfer paths in the eight-phase drive. FIG. 7 is a schematic diagram illustrating the layout of electrodes in the eight-phase drive. FIG. 8 is a timing chart of eight-phase drive pulses which are supplied to the vertical charge transfer paths shown in FIG. 6. FIG. 9 is a time chart illustrating a method of controlling the eight-phase drive vertical charge transfer paths in the solid-state imaging device in accordance with the invention. It should be noted that portions which are equivalent to those shown in FIGS. 1 to 5 are denoted by the same reference numerals, and a redundant description will be omitted.

In the solid-state imaging device in accordance with this embodiment, driving pulse signals serve as pulse signals for eight-phase drive. The transfer electrodes 53 are formed as the eight-phase transfer electrodes V1 to V8 are repeatedly provided. Of these transfer electrodes V1 to V8, those connected to the photodiodes 31 through transfer gates 55 are the first transfer electrodes (V2, V4, V6, and V8) 53a, whereas those not connected to the photodiodes 31 are the second transfer electrodes (V1, V3, V5, and V7) 53b.

In the method of driving the solid-state imaging device in accordance with this embodiment, since the driving pulse signal is the pulse signal for the eight-phase drive, of the eight-phase electrodes, at different times six electrodes are set to the low level, while two electrodes are set to the low level. As this arrangement is alternately repeated, the charge in a packet is moved with the lapse of time.

Times t1 to t19 constitute one cycle of the charge transfer, and of the eight-phase electrodes V1 to V8, six electrodes (V1 to V4, V6, and V8) are set to the low level at the time t1.

The driver 47 supplies the eight-phase drive pulses φV1 to φV8 to the electrodes V1 to V8. Each vertical charge transfer path 51 transfers the charges upwardly (vertically) from below in the drawing in the eight-phase drive in response to the drive pulses φV1 to φV8. The driver 47 supplies two-phase drive pulses φH1 and φH2 to the horizontal charge transfer path 37. The horizontal charge transfer path 37 receives charges from the vertical charge transfer paths 51 and transfers the charges from right to left (horizontally) in response to the drive pulses φH1 and φH2.

In the electrodes V1 to V8 on each vertical charge transfer path 51, a low-level voltage is applied to the electrodes shown hatched in FIG. 9, and the potential on the vertical charge transfer path 51 corresponding to those electrodes is shallow. Meanwhile, a high-level voltage is applied to the electrodes shown unhatched, and the potential on the vertical charge transfer path 51 corresponding to those electrodes is deep. Namely, packets are formed on the vertical charge transfer path of the unhatched electrodes, and charges are accumulated therein and transferred.

During the vertical transfer wait period S1, which is a horizontal transfer period, signal charges are read out from the photodiodes 31 to each vertical charge transfer path 51. At this time, in the vertical charge transfer paths 51, the electrodes V5 and V7 are set to the high level to form a packet, whereas the electrodes V1, V2, V3, V4, V6, and V8 are set to the low level to form potential barriers.

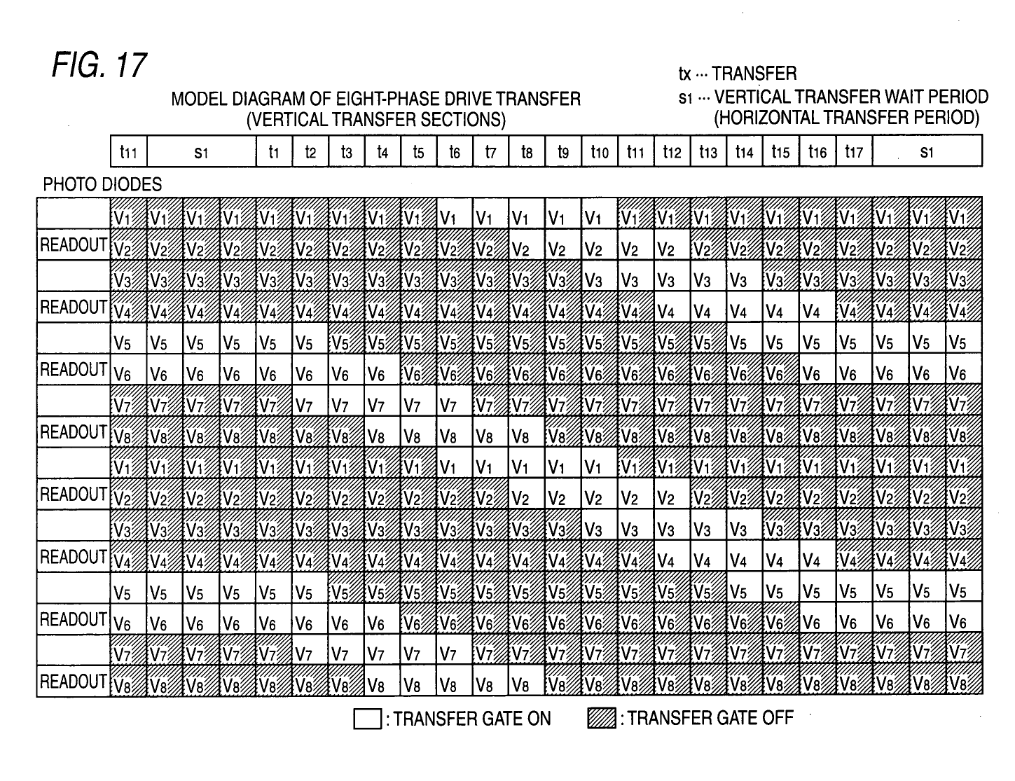

Thus, although the readout electrodes (electrodes V6 connected to the photodiodes 31 through transfer gates 55) are in the related art set to the high level during the vertical transfer wait period S1, as shown in FIG. 17, the readout electrodes in this embodiment (electrodes V6 connected to the photodiodes 31 through transfer gates 55) are set to the low level during the vertical transfer wait period S1, and the transfer gates are set in the off state, as shown in FIG. 9. As a result, with the eight-phase drive solid-state imaging device as well, advantages similar to those described above are offered.

Although a description has been given above by citing the solid-state imaging device having the so-called honeycomb structure, the invention is not limited to the same, and is also applicable to the solid-state imaging device having a square lattice structure.

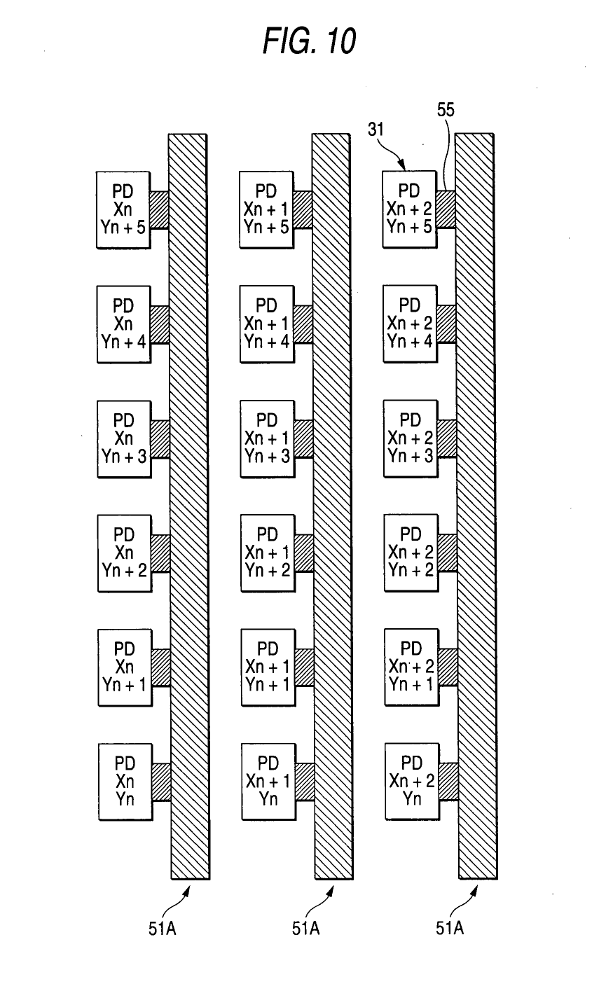

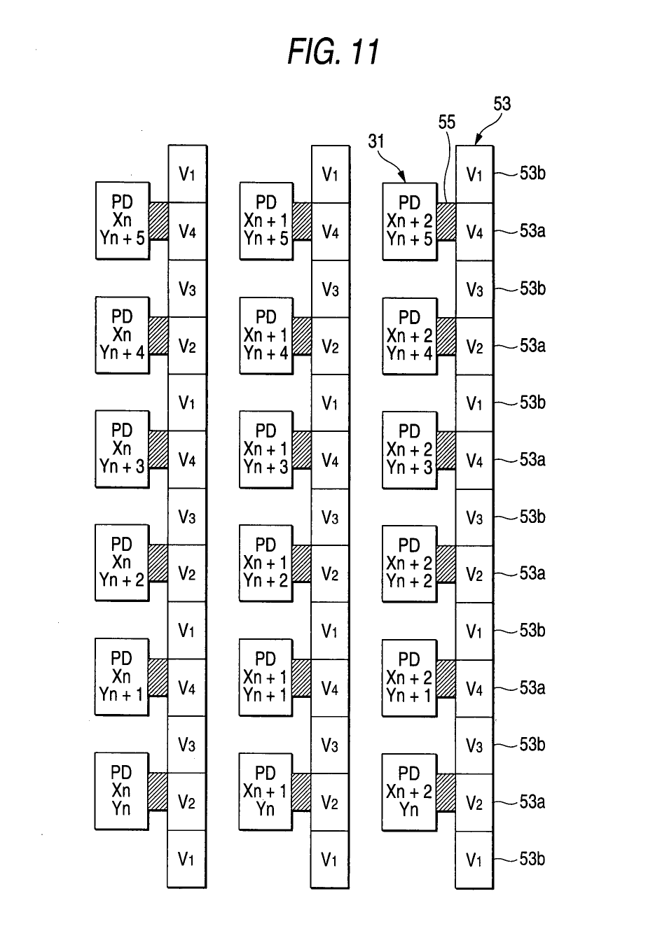

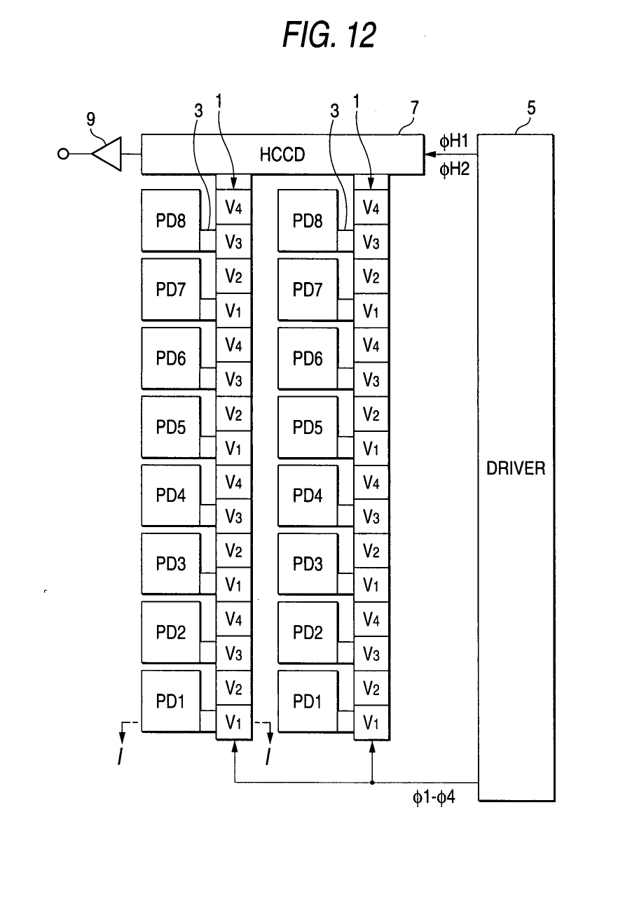

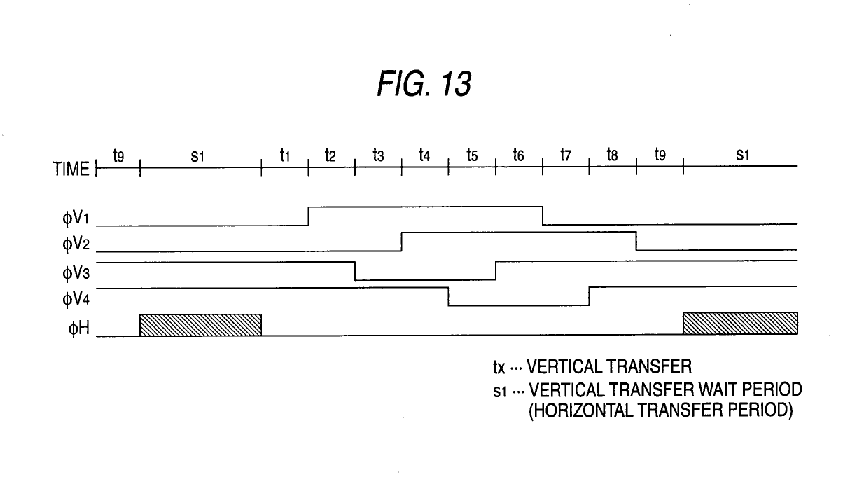

FIG. 10 is a plan view illustrating the layout of vertical transfer paths in the four-phase drive in the square lattice structure. FIG. 11 is a schematic diagram illustrating the layout of electrodes in the four-phase drive in the square lattice structure.

If the above drawings are collated with the method of driving the solid-state imaging device having the above-described honeycomb structure, it can be appreciated that imaging processing can be carried out by similar drive.

Thus, the solid-state imaging device and the method of driving the same in accordance with the invention are also applicable to the solid-state imaging device having a square lattice structure in which the photodiodes 31 are arranged in a matrix form along rectilinear vertical charge transfer paths 51A, and advantages similar to those described above are offered.

In addition, although in the above-described embodiments a description has been given by citing as an example the case in which the solid-state imaging device is a CCD type solid-state imaging device, the solid-state imaging device and the method of driving the same in accordance with the invention are not limited to the same, and can be suitably used in a MOS type imaging device as well, and similar advantages can be obtained.

According to the solid-state imaging device and the method of driving the same in accordance with the invention, when the signal charges are transferred along the charge transfer sections, a driving pulse signal is supplied to first transfer electrodes for effecting the reading and transfer of the electric charges from the photoelectric conversion elements and for effecting the transfer of the signal charges along the charge transfer sections and to second transfer electrodes each provided between adjacent ones of the first transfer electrodes to effect the transfer of the signal charges along the charge transfer sections, and when the transfer of the signal charges along the charge transfer sections is stopped, a pulse signal is supplied for constituting a barrier potential of a level at which the first transfer electrodes do not produce a dark current for the photoelectric conversion elements. Therefore, except during the transfer, the timing signal supplying section does not apply a barrier potential of a level for constituting storage electrodes to the readout electrodes. Namely, except during the transfer, the electrodes are set as storage electrodes by shunting the readout electrodes. Consequently, even in a case where the readout electrodes and two or more continuous electrodes which are not readout electrodes are alternately driven as storage electrodes, a voltage at the level of a storage electrode is not applied to the readout electrodes. Therefore, a depleted region is not produced at the readout gate of the photodiode, and electrons which are present in the vicinity of the interface cease to flow into the photodiode as a charge. As a result, a dark current ceases to be accumulated in the photodiode as the charge, thereby making it possible to reduce white defects contained in the image data.

The entire disclosure of each and every foreign patent application from which the benefit of foreign priority has been claimed in the present application is incorporated herein by reference, as if fully set forth.

What is claimed is:

1. A solid-state imaging device comprising:
a semiconductor substrate;
a pixel section on a surface layer of the semiconductor substrate, the pixel section including a plurality of photoelectric conversion elements for generating electric charges by responding to light arranged in a matrix form in a plurality of rows and columns;
a plurality of charge transfer sections on the surface layer of the semiconductor substrate, each of which is provided adjacent to each column of the pixel sections in a strip form, so as to transfer signal charges generated by the photoelectric conversion elements; and
a timing signal supplying section that supplies a drive pulse for effecting the transfer of the electric charges by the charge transfer sections,
wherein each of the charge transfer sections comprises:
first transfer electrodes for effecting the reading and transfer of the electric charges from the photoelectric conversion elements and for effecting the transfer of the signal charges along the charge transfer sections; and
second transfer electrodes each provided between adjacent ones of the first transfer electrodes to effect the transfer of the signal charges along the charge transfer sections, and
wherein the timing signal supplying section supplies a driving pulse signal to the first and second transfer electrodes when the signal charges are transferred along the charge transfer sections, and supplies a pulse signal for constituting a barrier potential of a level at which the first transfer electrodes do not produce a dark current for the photoelectric conversion elements when the transfer of the signal charges along the charge transfer sections is stopped.

2. The solid-state imaging device according to claim 1,
wherein the signal charges which are transferred are electrons, and the pulse signal for constituting the barrier potential is a low-level signal.

3. A method of driving a solid-state imaging device,
the solid-state imaging device comprising:
a semiconductor substrate;
a pixel section on a surface layer of the semiconductor substrate, the pixel section including a plurality of photoelectric conversion elements for generating electric charges by responding to light arranged in a matrix form in a plurality of rows and columns;
a plurality of charge transfer sections on the surface layer of the semiconductor substrate, each of which is provided adjacent to each column of the pixel sections in a strip form, so as to transfer signal charges generated by the photoelectric conversion elements; and
a timing signal supplying section that supplies a drive pulse for effecting the transfer of the electric charges by the charge transfer sections,
the method comprising:
when the signal charges are transferred along the charge transfer sections, supplying a driving pulse signal to first transfer electrodes for effecting the reading and transfer of the electric charges from the photoelectric conversion elements and for effecting the transfer of the signal charges along the charge transfer sections and to second transfer electrodes each provided between adjacent ones of the first transfer electrodes to effect the transfer of the signal charges along the charge transfer sections; and
when the transfer of the signal charges along the charge transfer sections is stopped, supplying a pulse signal for constituting a barrier potential of a level at which the first transfer electrodes do not produce a dark current for the photoelectric conversion elements.

4. The method of driving a solid-state imaging device according to claim 3,
wherein the driving pulse signal is a pulse signal for a four-phase drive.

5. The method of driving a solid-state imaging device according to claim 3,
wherein the driving pulse signal is a pulse signal for an eight-phase drive.

6. The solid-state imaging device according to claim 1,
wherein said plurality of photoelectric conversion elements are disposed by being offset by a half pitch in a column direction of the photoelectric conversion elements, and
each of said plurality of charge transfer sections is formed in such a manner as to meander in a wavelike pattern.

7. The method of driving a solid-state imaging device according to claim 3,
wherein the signal charges which are transferred are electrons, and the pulse signal for constituting the barrier potential is a low-level signal.
